(19) United States
(12) Patent Application Publication
(10) Pub. No.: US 2006/0109704 A1
(43) Pub. Date: May 25, 2006

(54) Nonvolatile memory device using resistor having multiple resistance states and method of operating the same

(76) Inventors: Sun-Ae Seo, Hwaseong-si (KR); In-Kyeong Yoo, Suwon-si (KR); Yoon-Dong Park, Yongin-si (KR); Myoung-Jae Lee, Suwon-si (KR)

Correspondence Address: HARNESS, DICKEY & PIERCE, P.L.C., P.O. BOX 8910, RESTON, VA, 20195, US

(21) Appl. No.: 11/267,576

(22) Filed: Nov. 7, 2005

(30) Foreign Application Priority Data
Nov. 6, 2004 (KR) 10-2004-0090152

(51) Int. Cl. G11C 11/00

(52) U.S. Cl. 365/148

(57) ABSTRACT

A nonvolatile memory device and method that uses a resistor having various resistance states. The memory device may include a switching device and a resistor. The resistor may be electrically connected with the switching device and may have one reset resistance state and at least two or more set resistance states.

### PRIORITY STATEMENT

This application claims the benefit of Korean Patent Application No. 10-2004-0090152, filed on Nov. 6, 2004, in the Korean Intellectual Property Office, the disclosure of which is incorporated herein in its entirety by reference.

### BACKGROUND OF THE INVENTION

1. Field of the Invention

Example embodiments of the present invention relate to a nonvolatile memory device using a resistor having multiple resistance states and method of operating the same.

2. Description of the Related Art

Semiconductor memory devices may have a high degree of integration, that is, a large number of memory cells per unit area, may operate at high speed, and may be driven at low power. Research into such semiconductor memory devices is ongoing and various types of memory devices are under development.

Generally, a semiconductor memory device may include many memory cells connected together. A representative memory device may be a dynamic random access memory (DRAM). A unit memory cell of the DRAM generally may include a switch and a capacitor, and may have high integration and/or high speed. However, a DRAM is a volatile memory device which loses all data stored therein when power is off.

A flash memory is a representative example of a nonvolatile memory device that can conserve stored data even after power is off. Unlike a volatile memory, for example, DRAM, flash memory has a characteristic of non-volatility but may have a lower degree of integration and/or a lower speed, compared to DRAM.

Examples of nonvolatile memory devices that are under development include magnetic random access memory (MRAM), ferroelectric random access memory (FRAM), and phase-change random access memory (PRAM).

The MRAM stores data using a change in magnetization direction at a tunnel junction, the FRAM stores data using a polarization characteristic of a ferroelectric material. Each has advantages. As described above, memory devices are being developed to increase integration, data retention, and/or operating speed, and be driven with lower power.

PRAM stores data using a change in resistance according to a phase change of a material. PRAMs may have a structure including a resistor and a switch (transistor). In a PRAM, the phase of the resistor is changed into a crystalline state or an amorphous state by controlling a formation temperature of the resistor. Generally, resistance in the amorphous state is higher than that in the crystalline state and the memory device is operated using a difference in the resistance.

The non-volatile memory devices thus far that use resistance characteristics operate using only two resistance states designated as “1” and “0”, respectively.

### SUMMARY OF THE INVENTION

Example embodiments of the present invention provide an operation method of a nonvolatile semiconductor memory device having a structure including one resistor and one switch and having a simpler structure, a higher speed, and/or operable at lower power.

According to an example embodiment of the present invention, there is provided a nonvolatile semiconductor memory device, the memory device using a resistive layer having multiple resistance states, including a switching device and a resistive layer electrically connected with the switching device and having one reset resistance state and at least two or more set resistance states.

In an example embodiment, the switching device may include a semiconductor substrate, a first impurity region and a second impurity region formed in the semiconductor substrate, and a gate structure contacting the first and second impurity regions and having a gate insulation layer and a gate electrode layer sequentially formed on the semiconductor substrate, the resistive layer being electrically connected with the second impurity region.

In an example embodiment, the first and second impurity regions and the gate structure may be covered with an interlayer insulation layer and the second impurity region may be electrically connected with the resistive layer through a contact plug passing through the interlayer insulation layer.

In an example embodiment, the resistive layer may include a transition metal oxide.

In an example embodiment, the resistive layer may include at least one material selected from the group consisting of NiO, TiO₂, HfO, Nb₂O₅, ZnO, ZrO₂, WO₃, CoO, GST (Ge₂Sb₂Te₅), PCMO(PrₓCa₁₋ₓMnO3).

In an example embodiment, the memory device may further include a comparator controlling a resistance state of the resistive layer by controlling a current value flowing through the resistor.

According to another example embodiment of the present invention, there is provided an operation method of a nonvolatile memory device having a switching device and a resistive layer electrically connected with the switching device and having one reset resistance state and at least two or more set resistance states, the method including controlling a resistance state of the resistive layer by controlling a current value flowing through the resistive layer while a resistance state of the resistive layer changes from the reset resistance state to the set resistance state.

In an example embodiment, the method may include comparing the current value flowing through the resistive layer with a reference current value and when the current value is greater than the reference current value, cutting off power supplied to the resistor.

In an example embodiment, the comparing of the current value with the reference current value may be performed by a comparator electrically connected with the resistor.

### BRIEF DESCRIPTION OF THE DRAWINGS

The present invention will become more apparent by describing in detail example embodiments thereof with reference to the attached drawings in which:

FIG. 1 is a view of a nonvolatile memory device that uses a resistive layer having multiple resistance states according to an example embodiment of the present invention;

FIG. 2 is a view of a nonvolatile memory device of a structure such that a resistive layer having multiple resistance states according to an example embodiment of the present invention is connected with a drain region of a transistor;

FIG. 3 is a graph illustrating multiple resistance states of a nonvolatile memory device that uses a resistor having one reset resistance state and one set resistance state;

FIGS. 4A and 4B are views graphs illustrating a current characteristic of a nonvolatile memory device that uses a resistor having multiple resistance states according to an example embodiment of the present invention; and

FIG. 5 is a view explaining an operation principle of a nonvolatile memory device that uses a resistor having multiple resistance states according to an example embodiment of the present invention.

### DETAILED DESCRIPTION OF EXAMPLE EMBODIMENTS OF THE INVENTION

The present invention will now be described more fully with reference to the accompanying drawings, in which example embodiments of the invention are shown.

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

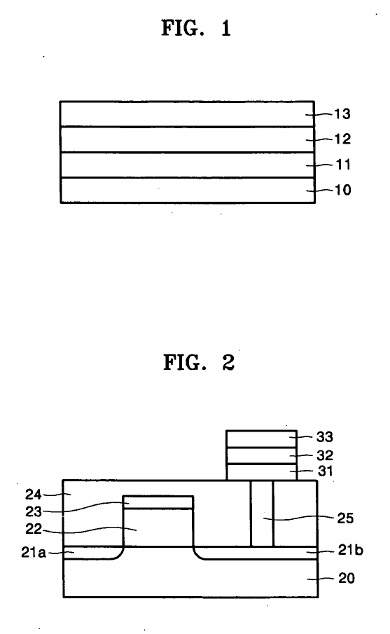

FIG. 1 is a view of a resistor region of a nonvolatile memory device that uses a resistive layer having multiple resistance states according to an example embodiment of the present invention. Referring to FIG. 1, the resistor of the memory device may include a lower structure 10, a lower electrode 11, a resistive layer 12, and an upper electrode 13, sequentially stacked.

The lower substrate 10 of FIG. 1 may be a transistor structure or a diode structure which can perform a switch function. The transistor structure will be described later. The lower electrode 11 and the upper electrode 13 may be made of a material used for an electrode of a general semiconductor memory device.

The resistive layer 12 may function as a data storage having multiple resistance states. The resistive layer 12 may be made of a non-conductive material having a lower conductivity and may be made of a transition metal oxide. For example, the resistive layer 12 may be made of at least one material selected from the group consisting of NiO, TiO₂, HfO, Nb₂O₅, ZnO, ZrO₂, WO₃, CoO, GST (Ge₂Sb₂Te₅), and PCMO(PrₓCa₁₋ₓMnO3).

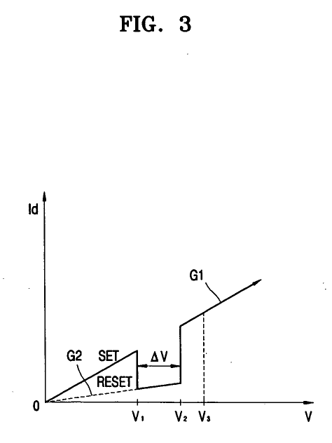

FIG. 2 is a view of a structure of a nonvolatile memory device that uses a resistive layer having multiple resistance states according to an example embodiment of the present invention. In FIG. 2, a structure of a memory device including one resistive layer 32 and one switch is illustrated. Although a transistor has been used as the switching device, a diode may be also used.

A first impurity region 21a and a second impurity region 21b may be formed in a semiconductor substrate 20. The first impurity region 21a may be referred to as a source and the second impurity region 21b may be referred to as a drain. A gate structure may be formed on the semiconductor substrate 20 contacting the source 21a and the drain 21b. The gate structure may include a gate insulation layer 22 and a gate electrode layer 23.

The source 21a, the drain 21b, and the gate structure may be covered with an interlayer insulation layer 24. A contact plug 25 may be formed in the interlayer insulation layer 24 of a region that corresponds to the drain 21b. The contact plug 25 may be electrically connected with a lower electrode 31 on which the resistive layer 32 and an upper electrode 33 are sequentially formed.

In an example embodiment, the resistive layers 12, 32 may include a chalcogenide.

For example, the resistive layers 12, 32 may include chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the resistive layers 12, 32 may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the resistive layers 12, 32 may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the resistive layers 12, 32 is described above as being formed primarily of ternary phase-change chalcogenide alloys, the chalcogenide alloy of the resistive layers 12, 32 could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

In an example embodiment, resistive layers 12, 32 may be made of a transition metal oxide having multiple resistance states, as described above. For example, the resistive layers 12, 32 may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃).

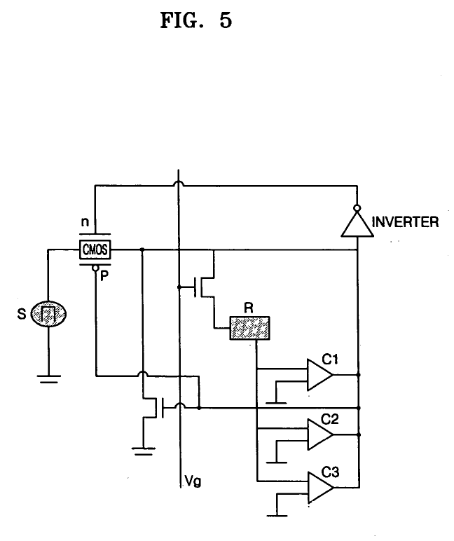

The resistive layer 32 may be electrically connected with a comparator, described later with reference to FIG. 5.

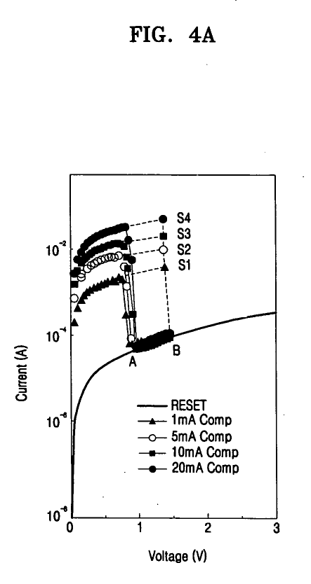

An operation principle of the nonvolatile memory device that uses a resistive layer according to an example embodiment of the present invention will be described with reference to FIG. 3. FIG. 3 is a graph illustrating a drain current measured according to an electrical potential applied to the resistive layer 32.

Referring to FIG. 3, the resistive layer 32 may represent a two-state resistance characteristic. If a voltage applied to the resistive layer 32 is gradually increased from zero, current increases along a line G1 in proportional to the voltage. A state following the line G1 may be referred to as a set state. If a voltage in a range of V1-V2 is applied, resistance increases so that current reduces, following a line G2. A state following the line G2 may be referred to as a reset state. If a voltage greater than V2 (V2>V1) is applied, the resistance reduces and thus the current increases, following the line G1 again.

An electrical characteristic that allows the resistive layer 32 to be used for data storage of a memory device will be described below. The electrical characteristic of the resistive layer 32 when a voltage in a range greater than V1 is applied to the resistive layer 32 has an influence on the electrical characteristic that appears when a voltage smaller than V1 is applied later.

For example, if a voltage in a range of V1-V2 is applied to the resistive layer 32 and then a voltage smaller than V1 is applied again, a current flowing through the resistive layer 32 is measured to follow the line G2. If V3 in a range greater than V2 is applied to the resistive layer 32 and then a voltage smaller than V1 is applied again, a current is measured to follow the line G1. From the foregoing, it is known that an electrical characteristic of the resistive layer 32 due to application of a voltage in the range that is greater than V1 (range of V1-V2 or range greater than V2) remains, not disappearing.

In an example embodiment, the transition metal oxide can be a material used for the resistive layer 32 and applied to the nonvolatile memory device.

In an example embodiment, for data recording, data can be recorded with a state of the resistive layer 32 when a voltage in a range of V1-V2 is applied, designated for a state “0” and a state of the resistive layer 32 when a voltage in a range greater than V2 is applied, designated for a state “1”.

In an example embodiment, for data reading, a voltage in a range smaller than V1 may be applied and a drain current value ‘Id” is measured, so that whether data stored in the resistive layer 32 is the state “0” or the state “1” is known. The designation of the state “0” and the state “1” are arbitrary and may be reversed.

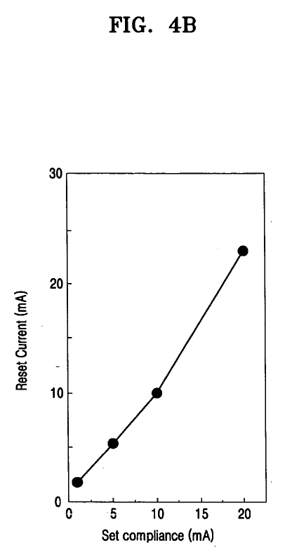

An operation principle of the nonvolatile memory device that uses a resistive layer will be described with reference to FIG. 4A. FIG. 4A is a graph illustrating an operation characteristic of a nonvolatile memory device that uses a resistive layer having multiple resistance states according to an example embodiment of the present invention.

Referring to FIG. 4A, one reset state and four set states are represented. The set states may include a first resistance state ‘1 mA Comp’, a second resistance state ‘5 mA Comp’, a third resistance state ‘10 mA Comp’, and a fourth resistance state ‘20 mA Comp’. A relationship of resistance's size in the respective resistance states is given by first resistance state>second resistance state>third resistance state>fourth resistance state.

Referring to FIG. 4A, the resistive layer 32 of the nonvolatile memory device may operate using two or more set states. Having multiple set states makes it possible to diversify and/or increase a type of data stored in the resistive layer 32.

A method of allowing the resistive layer 32 to have four set resistance states will be described with reference to FIG. 3 and FIG. 4A. In FIG. 3, a voltage applied to the resistive layer 32 is gradually increased, resistance changes from the set state to the reset state at V1 and changes from the reset state to the set state at V2. Accordingly, a process during which the resistance changes from the reset state to the set state may be a continuous process. At this point, the changed resistance may determine resistance of the resistive layer 32. As a result, it is possible to arbitrarily control the resistance of the resistive layer 32 by limiting a current value flowing through the resistive layer 32 when the resistance changes from the reset state to the set state.

Referring again to FIG. 4A, it is possible to control a current value flowing through the resistive layer 32 at a point B where the resistance changes from the reset state to the set state. It is possible to fix the resistive layer to the first resistance state by setting a current flowing through the resistive layer 32 to S1. The current value fixed at this point may be referred to as a set compliance current. The set compliance current at S1 is 1 mA according to an example embodiment of the present invention. It is possible to control the resistive layer 32 at a desired resistance state by controlling the set compliance currents at S2, S3, and S4 to become 5 mA, 10 mA, and 20 mA (or other desired current), respectively, in the same manner.

FIG. 4B is a graph illustrating the resistance states of the resistive layer 32 when the set compliance currents are controlled to 1 mA, 5 mA, 10 mA, and 20 mA at a point B of FIG. 4A, respectively. The graph illustrates a reset current value for each of the resistance states (set compliance current value) at the point A of FIG. 4A where the resistance changes from the set state to the reset state.

Using this characteristic, the resistance state of the resistive layer 32 may be controlled to a desired state, so that multi-state data can be recorded in the resistive layer 32 which is the data storage. Also, as described above, reading of the data recorded in the resistive layer 32 can be performed by applying a voltage smaller than a voltage at the point A of FIG. 4A to the resistive layer 32 in order to read a drain current value.

Referring to FIG. 5, a data recording method of the nonvolatile memory device that uses a resistor having the multiple resistance states will be described in detail with reference to an equivalent circuit diagram. Referring to FIG. 5, a resistor R is electrically connected with comparators C1, C2, and C3. The comparators C1, C2, and C3 are connected with a NMOS(n) of a CMOS through an inverter and directly connected with a PMOS(p) of the CMOS.

Comparison current values of the comparators C1, C2, and C3 may be set to 1 mA, 5 mA, and 10 mA, respectively. If a voltage that corresponds to the point B of FIG. 4A is applied, the resistor R changes from the reset state to the set state, so that the resistance reduces. At this point, if the resistor R is to be controlled to the first resistance state ‘1 mA Comp’ of FIG. 4A, the comparator C1 may be set to an on-state and the comparators C2 and C3 may be set to an off-state. Then, a voltage that corresponds to the point B may be applied to the resistor R and a current following in the resistor R gradually increases. If the current value reaches 1 mA, the comparator C1 operates and an output “1” is transferred to the CMOS. Referring to FIG. 5, a value “1” is converted into a value “0” by the inverter and the converted value is transferred to an NMOS and the value “1” is directly transferred to the PMOS. Therefore, both the NMOS and the PMOS are in an off-state and power supplied from a power supply S is cut off, so that the resistance state of the resistor R is fixed to the first resistance state.

In the same manner, if the resistor R is to be set to the second resistance state of FIG. 4A, only the comparator C2 is set to an on-state. If the resistor R is to be set to the third resistance state, only the comparator C3 is set to an on-state. Accordingly, the resistance state of the resistor R can be controlled to a desired state.

Example embodiments of the present invention may have one or more of the following advantages.

It is possible to store a large amount of information in a unit cell having a structure of one resistor-one switch structure (1R-1S structure) using a resistor having multiple resistance states for data storage.

The unit cell structure of a nonvolatile memory device may be simpler and a generally and widely known semiconductor process, for example, a conventional DRAM manufacturing process can be used as is, so that productivity may be increased and manufacturing cost reduced.

Because information can be stored and read in a simpler manner directly using the resistance characteristic of the resistor, a high-speed operation characteristic may be achieved.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A nonvolatile semiconductor memory device comprising:
a switching device; and
a resistive layer electrically connected to the switching device and having one reset resistance state and at least two or more set resistance states.

2. The memory device of claim 1, wherein the switching device comprises:
a semiconductor substrate;
a first impurity region and a second impurity region formed in the semiconductor substrate; and
a gate structure contacting the first and second impurity regions, the gate structure including a gate insulation layer and a gate electrode layer sequentially formed on the semiconductor substrate, the resistive layer being electrically connected to the second impurity region.

3. The memory device of claim 2, further comprising:
an interlayer insulative layer coating the gate structure and the first and second impurity regions; and
one or more contact plugs, formed in the interlayer insulative layer, wherein the second impurity region is electrically connected to the resistive layer via the one or more contact plugs.

4. The memory device of claim 1, wherein the resistive layer comprises a transition metal oxide.

5. The memory device of claim 1, wherein the resistive layer comprises at least one material selected from the group consisting of NiO, TiO₂, HfO, Nb₂O₅, ZnO, ZrO₂, WO₃, CoO, GST (Ge₂Sb₂Te₅), and PCMO (PrₓCa₁₋ₓMnO₃).

6. The non-volatile memory device of claim 4, wherein the transition metal oxide layer is formed of a chalcogenide material.

7. The non-volatile memory device of claim 6, wherein the chalcogenide material includes GST (Ge₂Sb₂Te₅).

8. The memory device of claim 1, further comprising a comparator controlling a resistance state of the resistive layer by controlling a current value flowing through the resistive layer.

9. A nonvolatile memory device array comprising a plurality of nonvolatile memory devices of claim 1.

10. A method of operating a nonvolatile memory device having a switching device and a resistive layer electrically connected with the switching device, the resistive layer having one reset resistance state and at least two or more set resistance states, the method comprising:
controlling a resistance state of the resistive layer by controlling a current value flowing through the resistive layer when a resistance state of the resistive layer changes from at least one of the reset resistance states to the set resistance state.

11. The method of claim 10, furthering comprising:
comparing the current value flowing through the resistive layer with a reference current value and when the current value is greater than the reference current value, cutting off power supplied to the resistive layer.

12. The method of claim 11, wherein the comparing of the current value with the reference current value is performed by a comparator electrically connected with the resistive layer.

13. The method of claim 10, wherein the switching device includes
a semiconductor substrate;
a first impurity region and a second impurity region formed in the semiconductor substrate; and
a gate structure contacting the first and second impurity regions, the gate structure including a gate insulation layer and a gate electrode layer sequentially formed on the semiconductor substrate, the resistive layer being electrically connected to the second impurity region.

14. The method of claim 10, wherein the resistive layer comprises a transition metal oxide.

15. The method of claim 10, wherein the resistive layer comprises at least one material selected from the group consisting of NiO, TiO₂, HfO, Nb₂O₅, ZnO, ZrO₂, WO₃, CoO, GST (Ge₂Sb₂Te₅) and PCMO(PrₓCa₁₋ₓMnO₃).

16. The method of claim 14, wherein the transition metal oxide layer is formed of a chalcogenide material.

17. The method of claim 16, wherein the chalcogenide material includes GST (Ge₂Sb₂Te₅).

18. A nonvolatile memory device operated in accordance with the method of claim 10.

19. A method of forming a nonvolatile memory device comprising:
forming first and second impurity regions in a substrate;
forming a gate insulative layer on the substrate;
forming a gate electrode layer on the gate insulative layer to form a gate structure;
removing portions of the gate insulative layer and the gate electrode layer to expose the first and second impurity regions;
forming an interlayer insulative layer on the gate structure and the first and second impurity regions;
forming holes in the interlayer insulative layer to access the first and second impurity regions;
filling the holes with contact plugs; and
forming a lower electrode over the contact plug;
forming a resistive layer, having one reset resistance state and at least two or more set resistance states, on the lower electrode; and
forming an upper electrode on the resistive layer.

20. A nonvolatile memory device formed in accordance with the method of claim 19.
